(19) United States
(12) Patent Application Publication
(10) Pub. No.: US 2010/0127706 A1
(43) Pub. Date: May 27, 2010

(54) SUBSTRATE FOR ORGANIC ELECTROLUMINESCENT ELEMENT, AND ORGANIC ELECTROLUMINESCENT ELEMENT

(75) Inventor: Kiyoshi ITOH, Tokyo (JP)

Correspondence Address: LADAS & PARRY LLP, 224 SOUTH MICHIGAN AVENUE, SUITE 1600, CHICAGO, IL, 60604, US

(73) Assignee: DAI NIPPON PRINTING CO., LTD., Tokyo-to (JP)

(21) Appl. No.: 12/695,325

(22) Filed: Jan. 28, 2010

Related U.S. Application Data
(62) Division of application No. 11/390,746, filed on Mar. 28, 2006.

(30) Foreign Application Priority Data
Mar. 29, 2005 (JP) 2005-095888

(51) Int. Cl. G01R 33/60

(52) U.S. Cl. 324/316

(57) ABSTRACT

The object of the present invention is to provide a substrate for an organic EL element capable of forming an organic EL layer efficiently in a highly precise pattern in a short period of time, and an organic EL element having the preferable electric characteristics.

To attain the object, the invention provides a substrate for an organic electroluminescent element comprising a base material, an electrode layer formed in a pattern on the base material, and a photocatalyst containing layer formed to cover the electrode layer and contains a photocatalyst and a binder so as to show the wettability change by the action of the photocatalyst accompanied by the energy irradiation, wherein the photocatalyst containing layer contains a portion with the signal intensity of the electron spin resonance spectrum derived from the hydroxy radical increased to 1,000 times or more in 1 second within 600 seconds of the start of the irradiation of the ultraviolet ray at the time of measuring the electron spin resonance spectrum while irradiating the ultraviolet ray.

### BACKGROUND OF THE INVENTION

1. Field of the Invention

The present invention relates to an organic electroluminescent element used preferably for various kinds of displays, light emitting elements, or the like, and a substrate for an organic electroluminescent element used for the production thereof.

2. Description of the Related Art

Conventionally, in the production method for an organic electroluminescent (hereinafter, also referred to as “organic EL”) element, an organic EL layer is formed by the photolithography method or the mask deposition method. However, the photolithography method involves a problem of the process complication and the high cost, and furthermore, the mask deposition method involves a problem of the yield and the cost due to the need of the expensive vacuum apparatus.

Therefore, as a method for patterning the organic EL layer, a method of using a photocatalyst has been proposed recently (see the official gazette of the Japanese Patent Application Laid-Open (JP-A) No. 2000-223270). This method is for patterning the organic EL layer by forming a wettability changeable layer to have the wettability change by an action of the photocatalyst accompanied by the energy irradiation, and forming a pattern on the wettability changeable layer surface by the wettability difference. According to the method, an organic EL layer can be formed highly precisely, utilizing the wettability difference so that the labor required for patterning can dramatically be eliminated, and thus it is advantageous. However, when the activity of the photocatalyst is low, the pattern formation requires the time so that the pattern is thickened by the energy spreading around, or the like. Accordingly, a problem is involved in that a highly precise pattern can hardly be formed.

Moreover, according to such a method, when the film thickness of the wettability changeable layer is large, or the like, the charge injection efficiency is lowered by the wettability changeable layer so that a problem is involved in that the light emission characteristics of the organic EL element are lowered. On the other hand, when the wettability changeable layer is made thinner, a problem is involved in that the patterns of different wettabilities can hardly be formed so as to lower the pattern characteristics.

### SUMMARY OF THE INVENTION

Then, a substrate for an organic EL element capable of forming an organic EL layer efficiently in a highly precise pattern in a short period of time, and an organic EL element having the preferable electric characteristics, using the same are awaited.

The present invention provides a substrate for an organic electroluminescent element comprising a base material, an electrode layer formed in a pattern on the base material, and a photocatalyst containing layer formed to cover the electrode layer and contains a photocatalyst and a binder so as to show the wettability change by an action of the photocatalyst accompanied by the energy irradiation, wherein the photocatalyst containing layer contains a portion with the signal intensity of the electron spin resonance spectrum derived from the hydroxy radical increased to 1,000 times or more in 1 second within 600 seconds of the start of the irradiation of the ultraviolet ray at the time of measuring the electron spin resonance spectrum while irradiating a ultraviolet ray.

According to the present invention, since the increasing ratio of the signal intensity derived from the hydroxy radial in a predetermined time from the start of the energy irradiation is of a certain level or more, the activity of the photocatalyst in the photocatalyst containing layer is high so that the generation efficiency of the active oxygen species in a short period of time can be made high. Therefore, the wettability of the photocatalyst containing layer can be changed efficiently in a highly precise pattern in a short period of time so that a highly precise organic EL layer can be formed according to the pattern. Moreover, according to the present invention, since the activity of the photocatalyst in the photocatalyst containing layer is high, even when the film thickness of the photocatalyst containing layer is thin, the wettability of the photocatalyst containing layer surface can be dramatically changed by the energy irradiation. Therefore, at the time of forming an organic EL element using a substrate for an organic EL element of the present invention, the charge injection efficiency decline by the photocatalyst containing layer, or the like can be made smaller.

Further, the present invention provides an organic electroluminescent element comprising an organic electroluminescent layer formed on the photocatalyst containing layer of the substrate for an organic electroluminescent element, and a counter electrode layer formed on the organic electroluminescent layer.

According to the present invention, the organic EL layer can be formed by utilizing the pattern with the wettability of the photocatalyst containing layer of the substrate for an organic EL element changed. Therefore, an organic EL element having the preferable light emission characteristics can be formed efficiently in a simple process.

The present invention provides a substrate for an organic electroluminescent element comprising a base material, an electrode layer formed in a pattern on the base material, a photocatalyst processing layer formed to cover the electrode layer and contains at least a photocatalyst, and a wettability changeable layer formed on the photocatalyst processing layer so as to have the wettability change by an action of the photocatalyst accompanied by the energy irradiation, wherein the photocatalyst processing layer contains a portion with the signal intensity of the electron spin resonance spectrum derived from the hydroxy radical increased to 1,000 times or more in 1 second within 600 seconds of the start of the irradiation of the ultraviolet ray at the time of measuring the electron spin resonance spectrum while irradiating a ultraviolet ray.

According to the present invention, since the intensity increasing ratio derived from the hydroxy radial in a predetermined time from the start of the energy irradiation is of a certain level or more, the activity of the photocatalyst in the photocatalyst processing layer is high so that the generation efficiency of the active oxygen species in a short period of time can be made high. Therefore, the wettability of the wettability changeable layer can be changed efficiently in a highly precise pattern within a short period of time so that a highly precise organic EL layer can be formed according to the pattern. Moreover, according to the present invention, since the activity of the photocatalyst in the photocatalyst processing layer is high, even when the film thickness of the photocatalyst processing layer and the wettability changeable layer is thin, a highly precise pattern can be formed. Thus, the light emission characteristics of an organic EL element formed using a substrate for an organic EL element of the present invention can be preferable, and thus it is advantageous.

The present invention further provides an organic electroluminescent element comprising an organic electroluminescent layer formed on the wettability changeable layer of the substrate for an organic electroluminescent element, and a counter electrode layer formed on the organic electroluminescent layer.

According to the present invention, the organic EL layer can be formed by utilizing the pattern with the wettability of the wettability changeable layer of the substrate for an organic EL element changed. Therefore, an organic EL element having the preferable light emission characteristics can be formed efficiently in a simple process.

According to the present invention, the wettability of the photocatalyst containing layer can be changed in a highly precise pattern efficiently in a short period of time so that a substrate for an organic EL element capable of forming a highly precise organic EL layer along the pattern can be provided. Moreover, since a highly precise pattern can be formed even when the film thickness of the photocatalyst containing layer is thin, the light emission characteristics of the organic EL element formed using a substrate for an organic EL element of the present invention can be made favorably, and thus it is advantageous.

### BRIEF DESCRIPTION OF THE DRAWINGS

FIG. 1 is a schematic cross-sectional view showing an example of a substrate for an organic EL element of the present invention.

FIGS. 2A to 2B are explanatory diagrams for explaining a method for patterning a photocatalyst containing layer of the present invention.

FIG. 3 is a schematic cross-sectional view showing another example of a substrate for an organic EL element of the present invention.

FIG. 4 is a schematic cross-sectional view showing an example of an organic EL element of the present invention.

FIG. 5 is a schematic cross-sectional view showing another example of an organic EL element of the present invention.

FIG. 6 is a graph showing the relationship between the light irradiation time and the signal intensity of the electron spin resonance derived from the hydroxy radical for the examples and the comparative examples of the present invention.

FIG. 7 is a graph showing the relationship between the light irradiation time and the signal intensity of the electron spin resonance derived from the hydroxy radical for the examples and the comparative examples of the present invention immediately after the start of the light irradiation.

### DESCRIPTION OF THE PREFERRED EMBODIMENTS

The present invention relates to an organic electroluminescent used preferably for various kinds of displays, light emitting elements, or the like, and a substrate for an organic electroluminescent element used for the production thereof. Hereinafter, each will be explained separately.

### A. Substrate for an Organic EL Element

First, a substrate for an organic EL element of the present invention will be explained. The substrate for an organic EL element of the present invention includes two embodiments according to the configuration difference. Hereinafter, each embodiment will be explained independently.

### 1. First Embodiment

First, a first embodiment of the substrate for an organic EL element of the present invention will be explained. The first embodiment of the substrate in the present invention is characterized in that a substrate for an organic electroluminescent element comprising a base material, an electrode layer formed in a pattern on the base material, and a photocatalyst containing layer formed to cover the electrode layer and contains a photocatalyst and a binder so as to show the wettability change by the action of the photocatalyst accompanied by the energy irradiation, wherein the photocatalyst containing layer contains a portion with the signal intensity of the electron spin resonance spectrum derived from the hydroxy radical increased to 1,000 times or more in 1 second within 600 seconds of the start of the irradiation of the ultraviolet ray at the time of measuring the electron spin resonance spectrum while irradiating a ultraviolet ray.

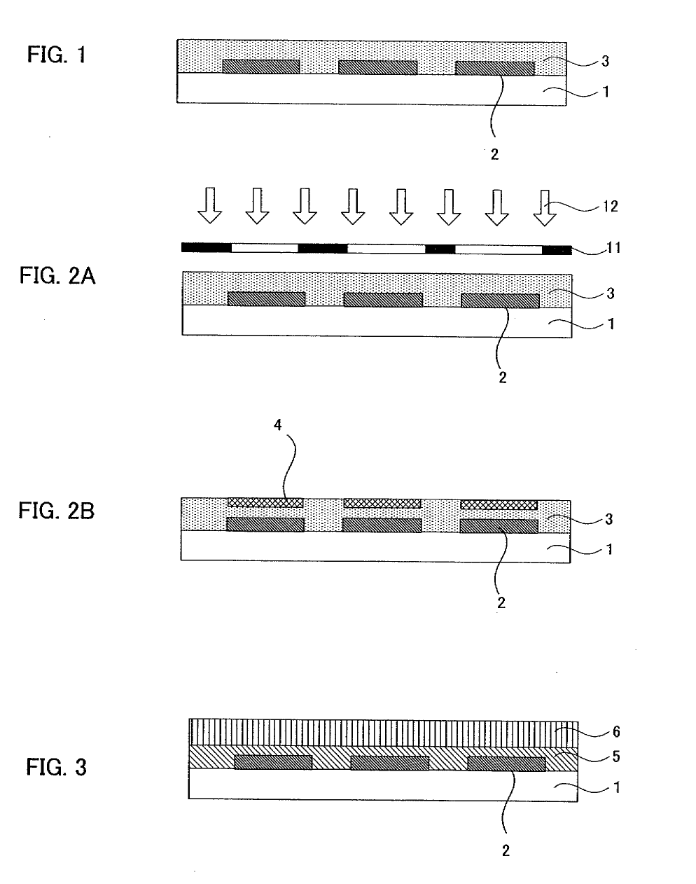

An example of a substrate for an organic EL element of this embodiment will be explained with reference to FIG. 1. The substrate for an organic EL element of this embodiment comprises a base material 1, an electrode layer 2 formed in a pattern on the base material 1, and a photocatalyst containing layer 3 formed so as to cover the electrode layer 2. Moreover, the photocatalyst containing layer includes a portion with the signal intensity of the electron spin resonance spectrum derived from the hydroxy radical increased to a predetermined value or more in 1 second within a predetermined time of the start of the irradiation of the ultraviolet ray at the time of measuring the electron spin resonance spectrum while irradiating an ultraviolet ray.

When an energy is irradiated to a photocatalyst containing layer containing a photocatalyst in the presence of oxygen or water, an active oxygen species is generated. The active oxygen species contributes to the modification or the decomposition of an organic substance such as a binder contained in the photocatalyst containing layer, and thereby the wettability of the photocatalyst containing layer is changed. Accordingly, a photocatalyst containing layer with a high photocatalyst activity and a large amount of the active oxygen species to be generated in a short period of time can efficiently change the wettability of the photocatalyst containing layer in a short period of time.

Here, evaluation of the activity degree of the photocatalyst accompanied by the energy irradiation can be carried out by the electron spin resonance (ESR). Specifically, it can be executed by calculating the generation increasing ratio of the active oxygen species by the photocatalyst containing layer in a certain period of time by the electron spin resonance method, that is, the increasing ratio of the signal intensity of the electron spin resonance spectrum derived from the hydroxy radical. A photocatalyst containing layer having a higher increasing ratio can generate a larger amount of the active oxygen species in a short period of time so that it has a high photocatalyst activity and can change the wettability of the photocatalyst containing layer surface in a short period of time.

According to this embodiment, a portion with the intensity increasing ratio of the electron spin resonance spectrum derived from the hydroxy radical to a predetermined value or more in 1 second within a predetermined time of the start of the irradiation of the energy at the time of measuring the electron spin resonance spectrum of the photocatalyst containing layer is included. Therefore, the generation efficiency of the active oxygen species of the photocatalyst contained in the photocatalyst containing layer is high so that a photocatalyst containing layer capable of changing the wettability efficiently in a short period of time can be provided.

Moreover, when the activity of the photocatalyst is low, the energy needs to be irradiated for a longer period of time at the time of patterning the photocatalyst containing layer. In this case, the pattern may be thickened by the energy spreading around, or the like. However, according to this embodiment, since the activity of the photocatalyst in the photocatalyst containing layer is high as mentioned above, the patterning operation can be carried out in a short period of time so that a highly precise pattern can be formed.

Moreover, when the film thickness of the photocatalyst containing layer is large, at the time of using the substrate for an organic EL element is used for an organic EL element, the charge injection efficiency may be lowered by the photocatalyst containing layer so as to lower the light emission characteristics of the organic EL element. However, according to this embodiment, since the activity of the photocatalyst in the photocatalyst containing layer is high, even when the film thickness of the photocatalyst containing layer is thin, the wettability of the photocatalyst containing layer can be changed efficiently so that one with a high wettability change degree can be provided. Therefore, the film thickness of the photocatalyst containing layer can be formed small so that at the time of using the same for an organic EL element, one with small charge injection efficiency decline can be provided. Hereinafter, the substrate for an organic EL element of this embodiment will be explained in detail for each configuration.

### (1) Photocatalyst Containing Layer

First, a photocatalyst containing layer used in this embodiment will be explained. The photocatalyst containing layer used in this embodiment formed to cover the electrode layer described later contains a photocatalyst and a binder so as to have the wettability change by the action of the photocatalyst accompanied by the energy irradiation. Moreover, the photocatalyst containing layer contains a portion with the signal intensity of the electron spin resonance spectrum derived from the hydroxy radical increased to 1,000 times or more in 1 second within 600 seconds of the start of the irradiation of the energy at the time of measuring the electron spin resonance spectrum. In this embodiment, among the above, it is preferable to include a portion which increases to 1,500 times or more, in particular, 2,000 times or more. Thereby, the activity of the photocatalyst in the photocatalyst containing layer can be made higher so that a photocatalyst containing layer capable of changing the wettability of the surface efficiently in a short period of time can be provided. The portion to have the increasing ratio of the signal intensity in one second to the value or more may be included by at least one point within 600 seconds.

In this embodiment, it is preferable that the portion to have the increasing ratio of the signal intensity to the value or more is included within 600 seconds of the start of the energy irradiation; more preferably, within 300 seconds; and particularly preferably within 100 seconds. Thereby, the photocatalyst containing layer can be activated earlier.

Here, the increasing ratio of the signal intensity can be measured and calculated by the following method. First, the photocatalyst containing layer and a radical trapping agent are set in an electron spin resonance measuring device. At the time, if a material reactive to the active oxygen species is contained in the photocatalyst containing layer, accurate measurement of the generation amount of the active oxygen species becomes difficult. Therefore, in this embodiment, the photocatalyst containing layer used for the measurement is formed excluding a material to be changed by the active oxygen species. Moreover, the radical trapping agent is added highly excessively with respect to the amount of the active oxygen species generated by the action of the photocatalyst accompanied by the energy irradiation. Subsequently, measurement of the electron spin resonance is started, while also starting the energy irradiation to the photocatalyst containing layer simultaneously. Thereafter, while irradiating the energy to the photocatalyst containing layer for a certain period of time, the electron spin resonance spectrum is measured in real-time so as to calculate the increasing ratio of the signal intensity from the obtained data.

The radical trapping agent used for the above-mentioned measurement can be suitably selected according to the shape, or the like of the photocatalyst containing layer. For example, it may be provided as an aqueous solution, a powder, or the like. As such a radical trapping agent, those commonly used as a radical trapping agent such as a pyrrolin oxide can be used.

Moreover, the energy used at the time of the above-mentioned measurement may be an energy capable of exciting the photocatalyst in the photocatalyst containing layer so that it can be suitably selected according to the kind of the photocatalyst. As such an energy, in general, it is set in a range of 400 nm or less, preferably in a range of 150 nm or more and 380 nm or less. As it will be described later, since the photocatalyst used preferably for the photocatalyst containing layer is a titanium dioxide, and a light beam of the above-mentioned wavelength is preferable as the energy for activating the photocatalyst function by the titanium oxide. As the light source to be used for the energy irradiation, for example, various light sources such as a mercury lamp, a metal halide lamp, a xenon lamp, and an excimer lamp can be presented. Moreover, the energy intensity is maintained at a constant level during the above-mentioned measurement.

According to the electron spin resonance method, the activity of the photocatalyst in a film state in the photocatalyst containing layer can be measured. The method is advantageous in that the activity of the photocatalyst can be measured in the same condition as in the case of actually using the photocatalyst containing layer for example for patterning a layer made of an organic substance, or the like.

In this embodiment, as the method for having the increasing ratio of the signal intensity of the electron spin resonance spectrum derived from the hydroxy radical of the photocatalyst containing layer to the value or more, for example, a method of improving the photocatalyst activity of the photocatalyst surface by adding a photocatalyst activity improving additive into the photocatalyst containing layer, a method of efficiently generating the active oxygen species by having the dispersion property of the photocatalyst in the photocatalyst containing layer favorably, or the like can be presented.

As the photocatalyst activity improving additive, for example, an oxide or a chloride of a metal, a sulfate, a sulfated substance, a nitrified substance, an organic acid salt, or the like can be presented. More specifically, a tin oxide, an iron chloride, a zinc nitrate, a silver acetate, or the like can be presented.

Moreover, as a method for improving the dispersion property of the photocatalyst in the photocatalyst containing layer, the following methods can be cited as examples: a method for improving the dispersion property by utilizing the electric repulsive force between the photocatalyst particles by providing the liquid property acidic at the time of producing the photocatalyst containing layer; a method of adding a dispersing agent or an aggregating agent for preventing aggregation of the photocatalyst; a method of agitating and dispersing under a certain condition for homogeneously dispersing each component; and a method of preventing aggregation by providing the binder component surrounding the photocatalyst bulky.

Moreover, it is preferable that the photocatalyst containing layer used in this embodiment has a function of transporting the electrons or the positive holes. Thereby, the electric characteristics of the organic EL element can be improved at the time of forming an organic EL element using a substrate for an organic EL element of this embodiment.

Here, as the photocatalyst used for the photocatalyst containing layer those known as photo semiconductors, for example a metallic oxide, such as a titanium dioxide (TiO₂) a zinc oxide (ZnO), a tin oxide (SnO₂), a strontium titanate (SrTiO₃), a tungsten oxide (WO₃), a bismuth oxide (Bi₂O₃), and an iron oxide (Fe₂O₃) can be presented. One or two or more kinds as a mixture can be selected and used from them. Among these, in the present embodiment, a titanium dioxide can be used preferably. The titanium dioxide is advantageous since it has high band gap energy, chemically stable without the toxicity, and easily obtainable.

The titanium dioxides include those of the anatase type and the rutile type belonging to the tetragonal system and those of the brookite type belonging to the ortho rhombic system. In this embodiment, either one can be used, or furthermore, these can be used as a mixture. Among these, in the present embodiment, it is preferable to use the anatase type titanium dioxide. The anatase type titanium dioxide has a 380 nm or less excitation wavelength. As the anatase type titanium dioxide, for example, a hydrochloric acid deflocculation type anatase type titania sol (STS-02 (average particle diameter 7 nm) manufactured by ISHIHARA SANGYO KAISHA, LTD., ST-K01 manufactured by ISHIHARA SANGYO KAISHA, LTD.), or a nitric acid deflocculation type anatase type titania sol (TA-15 (average particle diameter 12 nm) manufactured by Nissan Chemical Industries, Ltd.) can be presented.

Moreover, it is known that the brookite type titanium dioxide has a high photocatalyst activity so that it can be used preferably.

It can be confirmed that the photocatalyst is contained in the photocatalyst containing layer by the X ray photoelectron spectrometry, the Rutherford back scattering spectrometry, nuclear magnetic resonance spectrometry, the mass spectrometry or a combination of thereof.

The content of the photocatalyst in the photocatalyst containing layer is not particularly limited as long as it is an amount of the extent that the wettability of the photocatalyst containing layer can be changed without disturbing the transportation of the positive hole or the electron and to the extent that the photocatalyst containing layer can generate the active oxygen species. In general, the content can be set in the range 5 to 80% by weight, preferably in the range of 20 to 70% by weight.

Moreover, it is preferable that the binder used in this embodiment has the wettability change by the action of the photocatalyst accompanied by the energy irradiation. Thereby, a material for changing the wettability of the photocatalyst containing layer needs not be added separately in the photocatalyst containing layer.

No especial limitation is imposed on the material which changes its wettability by the action of the photocatalyst accompanied by the energy irradiation used in the present embodiment, as long as it is a binder which has a main chain that is not deteriorated or decomposed by the action of the photocatalyst. Examples include organopolysiloxane or the like. Among them, in the present embodiment, it is preferable that the organopolysiloxane is an organopolysiloxane containing a fluoroalkyl group. This is because the wettability of the photocatalyst containing layer can be dramatically changed by the action of the photocatalyst accompanied by the energy irradiation. As the organopolysiloxane containing a fluoroalkyl group, for example, those disclosed in JP-A No. 2000-249821 can be used.

Moreover, as to the method for forming the photocatalyst containing layer, for example, it can be formed by preparing a coating solution by dispersing a photocatalyst and an organopolysiloxane as the binder in a solvent as needed with other additives, and coating the coating solution on a base material. As the solvent to be used, an alcohol based organic solvent such as an ethanol and an isopropanol is preferable. The coating operation can be carried out by a known coating method such as spin coating, spray coating, dip coating, roll coating and bead coating. When an ultraviolet ray curable type component is contained as the binder, the photocatalyst containing layer can be formed by carrying out the curing process by irradiating an ultraviolet ray.

Other than the photocatalyst and the binder, surfactant can be included in the photocatalyst containing layer. Specifically, hydrocarbons of the respective series of NIKKO L BL, BC, BO, and BB manufactured by Nikko Chemicals Co., Ltd., and fluorine base or silicone base nonionic surfactants such as ZONYL FSN and FSO manufacture by Du Pont Kabushiki Kaisha, Surflon S-141 and 145 manufactured by ASAHI GLASS CO., LTD., Megaface F-141 and 144 manufactured by DAINIPPON INK AND CHEMICALS, Inc., FTERGENT F-200 and F251 manufactured by NEOS, UNIDYNE DS-401 and 402 manufactured by DAIKIN INDUSTRIES, Ltd., and Fluorad FC-170 and 176 manufactured by 3M can be cited. Furthermore, cationic surfactants, anionic surfactants and amphoteric surfactants can be used.

Other than the surfactants, oligomers and polymers such as polyvinyl alcohol, unsaturated polyester, acrylic resin, polyethylene, diallyl phthalate, ethylene propylene diene monomer, epoxy resin, phenol resin, polyurethane, melamine resin, polycarbonate, polyvinyl chloride, polyamide, polyimide, styrene-butadiene rubber, chloroprene rubber, polypropylene, polybutylene, polystyrene, polyvinyl acetate, polyester, polybutadiene, polybenzimidazole, polyacrylonitrile, epichlorohydrine, polysulfide, polyisoprene and the like can be included in the photocatalyst containing layer.

Furthermore, in addition to the photocatalyst, binder and surfactant, the photocatalyst containing layer may contain a metal salt such as an iron chloride, a copper nitrate, a tin oxide and a silver acetate, a metal oxide, metal fine particles of gold, silver, copper, iron, or the like, and a ultraviolet ray absorbing pigment such as a triazol.

A thickness of the photocatalyst containing layer in the present embodiment is preferably within the range from 10 nm to 1000 nm, more preferably from 10 nm to 500 nm, and particularly preferably, from 10 nm to 200 nm. If the photocatalyst containing layer is too thin, the wettability difference can not be shown clearly so that the wettability changeable pattern can hardly be formed. On the other hand, in the case the thickness of the photocatalyst containing layer is too thick, transportation of the positive hole or the electron can be disturbed so that the adverse effect may be posed to the electric characteristics of the organic EL element at the time of providing an organic EL element using the substrate for an organic EL element of the present embodiment.

### (2) Electrode Layer

Next, the electrode layer used in the present embodiment will be explained. The electrode layer of the embodiment is formed in a pattern on the base material which will be described later. Although the electrode layer used in the embodiment may either be an anode or a cathode, in general it is formed as an anode.

Moreover, the electrode layer may either be transparent or not, and it may be selected optionally according to the light taking out surface or the receiving surface or the like. At the time of providing an organic El element using a substrate for an organic EL element of the embodiment, for example in the case of taking out the light beam from the electrode layer side, the electrode layer needs to be transparent or semitransparent.

As the anode, it is preferable to use a conductive material having a large work function for facilitating the positive hole injection. Specifically, a metal having a large work function such as an ITO, an indium oxide, and a gold, a conductive polymer such as a polyaniline, a polyacetylene, a polyalkyl thiophene derivative, and a polysilane derivative, or the like can be presented.

Moreover, it is preferable that the electrode layer has a small resistance. In general, a metal material is used, however, an organic compound or an inorganic compound may be used as well.

As for the method of forming such electrode layer, a conventional forming method of the electrode can be employed. For example, PVD method such as vacuum deposition method, sputtering method, or ion plating method, or CVD method can be cited. For a patterning method of the electrode layer, there is no particular limitation imposed as long as a desired pattern can be formed precisely, however, photolithography method or the like can be cited as a specific example.

### (3) Base Material

The base material used in the present embodiment is not particularly limited as long as it supports the electrode layer and the photocatalyst containing layer mentioned above and it has a predetermined strength. In the embodiment, in the case the electrode layer has a predetermined strength, the electrode layer may serve also as the base material. In general, the electrode layer is formed on a base material having a predetermined strength.

The base material is not particularly limited as long as the electrode layer or the like can be formed. For example, whether or not the light transmission property is needed is determined optionally according to the light taking out surface or the receiving surface. Since it is in general preferable to have the base material side as the light taking out surface or the receiving surface, the base material is preferably made of a transparent material.

As the material for forming such a base material, for example, a glass plate of a soda lime glass, an alkaline glass, a lead alkaline glass, a borosilicate glass, an alumina silicate glass, a silica glass, or the like, or a resin base material capable of being shaped as a film or the like can be used. It is preferable that the resin used for the resin base material is a polymer material having relatively high solvent resistance and heat resistance. Specifically, a fluorine based resin, a polyethylene, a polypropylene, a polyvinyl chloride, a polyvinyl fluoride, a polystyrene, an ABS resin, a polyamide, a polyacetal, a polyester, a polycarbonate, a modified polyphenylene ether, a polysulfon, a polyallylate, a polyether imide, a polyether sulfon, a polyamide imide, a polyimide, a polyphenylene sulfide, a liquid crystalline polyester, a polyethylene terephthalate, a polybutylene terephthalate, a polyethylene naphthalate, a polymicroyxylene dimethylene terephthalate, a polyoxy methylene, a polyether sulfon, a polyether ether ketone, a polyacrylate, an acrylonitrile-styrene resin, a phenol resin, a urea resin, a melamine resin, an unsaturated polyester resin, an epoxy resin, a polyurethane, a silicone resin, an amorphous polyolefin or the like can be presented. Moreover, in addition to the examples, a polymer material satisfying predetermined conditions can also be used, and a copolymer of two or more kinds may be used as well. Furthermore, as needed, a base material having the gas barrier property of blocking the gas such as the moisture content and the oxygen can be used.

Moreover, in the present embodiment, a light shielding part may be provided on the base material. In the case the light shielding part is formed, by directing an energy from the base material side, the wettability of the photocatalyst containing layer surface in the portion without the light shielding part provided can be changed with no mask or drawing by a laser beam or the like used. It is therefore unnecessary to position a mask precisely onto the photocatalyst containing layer, and the step can be simplified. Consequently, it is unnecessary to use any expensive device for drawing irradiation, thereby producing an advantage for costs.

As to the position for forming such a light shielding part, there are the case of forming the light shielding part on the base material and forming the photocatalyst containing layer thereon, that is, between the base material and the photocatalyst containing layer, and the case of forming as a pattern on the surface on the side without the format ion of the photocatalyst containing layer of the base material.

The method for forming the light shielding part is not particularly limited, and may be appropriately selected in accordance with the property of the face where the light shielding part is to be formed, shielding property with respect to the required energy, and others. For instance, a metal thin film that is made of chromium or the like and formed into a thickness of about 1000 to 2000 Å by a sputtering method, a vacuum deposition method or the like is formed and patterned to form a shielding part. As the patterning method, an ordinary patterning method such as the sputtering can be used.

A method may be one by which a layer that contains light-shielding particles such as carbon particulates, metal oxides, inorganic pigments and organic pigments in a resin binder is formed in a pattern. As the resin binders that can be used, a polyimide resin, acrylic resin, epoxy resin, polyacrylamide, polyvinyl alcohol, gelatin, casein, cellulose and the like can be used singularly or in combination of two or more kinds, and furthermore a photosensitive resin and an O/W emulsion type resin composition such as emulsified reactive silicone can be used. A thickness of such resinous light shielding part can be set in the range of 0.5 to 10 μm. As a method of patterning such resinous light shielding part, methods such as a photolithography method and a printing method that are generally used can be used.

### (4) Substrate for an Organic EL Element

Next, a substrate for an organic EL element of this embodiment will be explained. The substrate for an organic EL element of this embodiment is not particularly limited as long as it has the base material, electrode layer and photocatalyst containing layer. For example, as needs arise, it may optionally have an insulation layer, a barrier layer, or the like.

Here, the substrate for an organic EL element of this embodiment may not have the wettability change of the photocatalyst containing layer. However, in this embodiment in particular, it is preferable that the wettability of the surface of the photocatalyst containing layer is changed in a pattern. Thereby, at the time of forming an organic EL element using the substrate for an organic EL element of this embodiment, the organic EL layer can be formed highly precisely along the wettability changeable pattern. Hereinafter, such a wettability changeable pattern will be explained.

### (Wettability Changeable Pattern)

The wettability changeable pattern to be formed on the photocatalyst containing layer can be selected suitably according to the shape of the organic El layer to be formed on the photocatalyst containing layer, and thus its pattern is not particularly limited.

In this embodiment, since the photocatalyst containing layer shows the characteristic change by the action of the photocatalyst accompanied by the energy irradiation, for example, as shown in FIGS. 2A to 2B, by irradiating an energy 12 in a pattern using a photo mask 11, or the like to the photocatalyst containing layer 3 (FIG. 2A), a wettability changeable pattern 4 with the wettability changed can be formed on the photocatalyst containing layer 3 (FIG. 2B). In general, the portion with the energy irradiation is used as a lyophilic region, and the region without the energy irradiation is used as a liquid repellent region.

Here, the lyophilic region is a region having a small contact angle with respect to a liquid, and it refers to a region having a good wettability to the organic EL layer forming coating solution used at the time of producing an organic EL element using a substrate for an organic EL element produced by the present embodiment. Moreover, the liquid repellent region is a region having a large contact angle with respect to a liquid, and it denotes a region having a poor wettability with respect to the organic EL layer forming coating solution.

It is preferable that the contact angles with respect to the organic EL layer forming coating solution in the lyophilic region formed by the energy irradiation and the liquid repellent region without the energy irradiation differ by at least 1° or more, preferably 5° or more, and particularly preferably 10° or more.

Moreover, in the region irradiated with energy, that is, in the lyophilic region, the contact angle with respect to a liquid lowers by the energy irradiation. Preferably, the contact angle with a liquid having a surface tension of 40 mN/m is 9° or less, more preferably, the contact angle with a liquid having a surface tension of 50 mN/m is 10° or less, and even more preferably the contact angle with a liquid having a surface tension of 60 mN/m is 10° or less for the following reason: in the case the contact angle in the portion with the energy irradiation, that is, the lyophilic region with respect to a liquid is high, spreading the organic EL layer forming coating solution may be poor in this portion at the time of forming the organic EL layer so that a problem of lacking of the organic EL layer, in particular, the light emitting layer or the like may be generated.

On the other hand, about the photocatalyst containing layer, in the region not irradiated with energy, that is, in the liquid repellent region, preferably, the contact angle with a liquid having a surface tension of 40 mN/m is 10° or more, more preferably, the contact angle with a liquid having a surface tension of 30 mN/m is 10° or more, and even more preferably the contact angle with a liquid having a surface tension of 20 mN/m is 10° or more. Since the portion without the energy irradiation is the portion required to have the liquid repellent, in the case the contact angle with respect to a liquid is small, due to the insufficient liquid repellent, the patterning characteristics may be lowered at the time of forming the organic EL layer.

The contact angle with respect to a liquid here is obtained from the results or a graph of the results of measuring (30 seconds after of dropping liquid droplets from a micro syringe) the contact angle with respect to liquids having various surface tensions using a contact angle measuring device (CA-Z type manufactured by Kyowa Interface Science, Co., Ltd). Moreover, at the time of the measurement, as the liquids having the various surface tensions, wetting index standard solution manufactured by JUNSEI CHEMICAL CO., LTD. were used.

The energy irradiation (exposure) in the present embodiment is the concept including the irradiation of any energy line capable of exciting the photocatalyst. In addition to the ultraviolet ray, the visible light beam and the infrared ray, the electromagnetic waves and the radiations of a wavelength shorter or longer than the same are included as well.

The energy irradiation method is not particularly limited as long as it is a method capable of changing the wettability of the photocatalyst containing layer. Moreover, the energy irradiation may be carried out using a mask such as a photo mask, with a purposed pattern formed. Thereby, the energy irradiation in a purposed pattern can be enabled so that the wettability of the photocatalyst containing layer can be changed in a pattern. At the time, the kind of the mask to be used is not particularly limited as long as the energy irradiation in a purposed pattern can be enabled. It may be a photo mask or the like with a light shielding part formed in a energy transmittable material, or it may be a shadow mask or the like with a hole part formed in a purposed pattern. As a material for the mask, specifically, an inorganic substance such as a metal, a glass or a ceramic, or an organic substance such as a plastic or the like, can be cited.

Furthermore, in the case a light shielding part is formed on the base material to be used, the energy irradiation may be the entire surface exposure from the base material side, utilizing the light shielding part. Thereby, the energy can be directed only to the photocatalyst containing layer at a position without formation of the light shielding part so as to change the wettability of the photocatalyst containing layer at the directed part. In this case, since it is unnecessary to use the mask or to irradiate a laser ray for drawing irradiation, the positioning or expensive device for drawing irradiation is not required. Thus it is advantageous.

For energy irradiation, ultraviolet ray is normally used. Specifically, a wavelength of the ultraviolet ray is set in a range of 400 nm or less, preferably in a range of 150 nm to 380 nm. This is because, as mentioned above, a preferable photocatalyst used in the photocatalyst containing layer is the titanium dioxide and it is preferable to use the light of the above wave length as energy to activate the photocatalyst action with the titanium dioxide.

As for the light source that can be used for such an energy irradiation, various light sources such as a mercury lamp, a metal halide lamp, a xenon lamp, and an excimer lamp can be cited. The energy can be irradiated using a laser such as an excimer or YAG. By using the laser to irradiate the energy, the positioning of the photomask mentioned above or the like becomes unnecessary, thus the wettability of the photocatalyst containing layer can be changed highly precisely without forming the light shielding part on the base material.

Moreover, in the case an anatase type titanium dioxide is used as the photocatalyst, since the excitation wavelength of the anatase type titanium dioxide is 380 nm or less, the energy irradiation can be carried out with an ultraviolet ray. For the light source which radiates such ultraviolet ray, a high pressure mercury lamp (154, 313, 365, 405, 436, 546, 577 nm), a superhigh pressure mercury lamp (250 to 600 nm), a metal halide lamp (250 to 600 nm), a xenon lamp (300 to 1100 nm), an excimer laser, or other ultraviolet ray light sources can be used.

The energy irradiation amount at the time of the energy irradiation is an irradiation amount necessary for changing the wettability of the photocatalyst containing layer by the action of the photocatalyst in the photocatalyst containing layer.

### 2. Second Embodiment

Next, a second embodiment of the substrate for an organic EL element in the present invention will be explained. The substrate of the second embodiment is characterized in that a substrate for an organic electroluminescent element comprising a base material, an electrode layer formed in a pattern on the base material, a photocatalyst processing layer formed to cover the electrode layer and contains at least a photocatalyst, and a wettability changeable layer formed on the photocatalyst processing layer so as to have the wettability change by the action of the photocatalyst accompanied by the energy irradiation, wherein the photocatalyst processing layer contains a portion with the signal intensity of the electron spin resonance spectrum derived from the hydroxy radical increased to 1,000 times or more in 1 second within 600 seconds of the start of the irradiation of the ultraviolet ray at the time of measuring the electron spin resonance spectrum while irradiating the ultraviolet ray.

For example, as shown in FIG. 3, a substrate for an organic EL element of this embodiment comprises a base material 1, an electrode layer 2 formed in a pattern on the base material 1, a photocatalyst processing layer 5 formed so as to cover the electrode layer 2, and a wettability changeable layer 6 formed on the photocatalyst processing layer 5. Moreover, the photocatalyst processing layer includes a portion with the signal intensity of the electron spin resonance spectrum derived from the hydroxy radical increased to a predetermined value or more in 1 second within a predetermined time of the start of the irradiation of the energy at the time of measuring the electron spin resonance spectrum while irradiating an energy.

According to this embodiment, since the generation efficiency of the active oxygen species of the photocatalyst contained in the photocatalyst processing layer is high so that the wettability of the wettability changeable layer can be changed efficiently in a short period of time. Moreover, the pattern cannot be thickened, or the like at the time of forming a pattern with the wettability changed on the wettability changeable layer.

Moreover, according to this embodiment, since the generation efficiency of the active oxygen species is high, even when the film thickness of the photocatalyst processing layer or the wettability changeable layer is provided small, the wettability of the wettability changeable layer can be changed efficiently so that the wettability change degree can be made larger. Therefore, the film thickness of the photocatalyst processing layer or wettability changeable layer can be formed small so that at the time of using the substrate for an organic EL element of this embodiment for an organic EL element, decline of the charge injection efficiency by the photocatalyst processing layer, the wettability changeable layer, or the like can be reduced. Hereinafter, each configuration of the substrate for an organic EL element of this embodiment will be explained in detail. As to the electrode layer and base material, since those same as the first embodiment can be used, detailed explanation is omitted here.

### (1) Photocatalyst Processing Layer

The photocatalyst processing layer used in this embodiment is not particularly limited as long as it is formed on the electrode layer and it contains at least a photocatalyst. In this embodiment, it is particularly preferable to have the function of transporting the electrons or the positive holes. Thereby, the electric characteristics of the organic EL element can be improved at the time of forming an organic EL element using a substrate for an organic EL element of this embodiment.

The photocatalyst processing layer contains a portion with the signal intensity of the electron spin resonance spectrum derived from the hydroxy radical increased to 1,000 times or more in 1 second within 600 seconds of the start of the irradiation of the energy at the time of measuring the electron spin resonance spectrum. In this embodiment, among the above, it is preferable to include a portion which increases to 1,500 times or more, in particular, 2,000 times or more. Thereby, the activity of the photocatalyst in the photocatalyst processing layer can be made higher so that a photocatalyst processing layer capable of changing the wettability of the wettability changeable layer efficiently in a short period of time can be provided. The portion to have the increasing ratio of the signal intensity in one second to the value or more may be included by at least one point within 600 seconds.

In this embodiment, it is preferable that the portion to have the increasing ratio of the signal intensity to the value or more is included within 600 seconds of the start of the energy irradiation; more preferably, within 300 seconds; and particularly preferably within 100 seconds. Thereby, the photocatalyst processing layer can be activated earlier. The signal intensity of the electron spin resonance spectrum can be measured by the method mentioned above.

Moreover, as the method for having the increasing ratio of the signal intensity of the electron spin resonance spectrum derived from the hydroxy radical of the photocatalyst processing layer to the value or more the following methods can be cited as examples: a method of improving the photocatalyst activity of the photocatalyst surface by adding a photocatalyst activity improving additive into the photocatalyst processing layer; and a method of efficiently generating the active oxygen species by having the dispersion property of the photocatalyst in the photocatalyst processing layer favorably, or the like. Since the same methods explained for the item of the photocatalyst containing layer of the first embodiment mentioned above can be used, detailed explanation is omitted here.

Moreover, the photocatalyst processing layer may be formed either with a photocatalyst alone or as a mixture of a photocatalyst and a binder. In the case of a photocatalyst processing layer comprising a photocatalyst and a binder, it is advantageous in that the photocatalyst processing layer can easily be formed. As to the binder used for the photocatalyst processing layer, the same binders used for the photocatalyst containing layer of the first embodiment can be used. Since the photocatalyst is same as those mentioned in the first embodiment, the explanation is omitted here.

Moreover, as the method for forming a photocatalyst processing layer comprising only a photocatalyst, for example, a sputtering method, a CVD method, and a method of using a vacuum film production method such as a vacuum deposition method can be presented. By forming the photocatalyst processing layer by the vacuum film production method, a photocatalyst processing layer containing only a photocatalyst can be provided as an even film.

As the method for forming a photocatalyst processing layer comprising only a photocatalyst, for example, when the photocatalyst is a titanium dioxide, a method of forming an amorphous titania so as to cover the electrode layer, and then having the phase change by baking to the crystalline titania, or the like can be presented. The amorphous titania used here can be obtained for example, by the hydrolysis and dehydration condensation of an inorganic salt of a titanium such as a titanium tetrachloride and a titanium sulfate, and hydrolysis and dehydration condensation of an organic titanium compound such as a tetraethoxy titanium, a tetraisopropoxy titanium, a tetra-n-propoxy titanium, a tetrabutoxy titanium and a tetramethoxy titanium in the presence of an acid. Then, it can be modified into an anatase type titanium by baking at 400° C. to 500° C., and into a rutile type titanium by baking at 600° C. to 700° C.

Moreover, a thickness of the photocatalyst processing layer is preferably from 10 nm to 1000 nm, more preferably from 10 nm to 500 nm, and most preferably from 10 nm to 200 nm. If the photocatalyst processing layer is too thin, it may be difficult to change the wettability of the wettability changeable layer. On the other hand, in the case the thickness of the photocatalyst processing layer is too thick, transportation of the positive hole or the electron can be disturbed so that the adverse effect may be posed to the electric characteristics of the organic EL element at the time of providing an organic EL element using the substrate for an organic EL element of the present embodiment.

### (2) Wettability Changeable Layer

The wettability changeable layer used in the present embodiment is not particularly limited as long as it contains a material which the wettability thereof changes by the action of the photocatalyst accompanied by the energy irradiation. As for the material which the wettability thereof changes by the action of the photocatalyst accompanied by the energy irradiation, it is the same as the binder contained in the photocatalyst containing layer explained in the first embodiment. Thus, the explanation is omitted here.

In the wettability changeable layer, the same surfactant, additives, or the like as the ones described in the first embodiment can be contained.

Furthermore, the wettability changeable layer may contain a charge transporting property improving substance for the purpose of improving the charge transporting property for transporting the electron or the positive hole.

A thickness of the wettability changeable layer is not particularly limited as long as it is a thickness of the extent that it can form a wettability changeable pattern as well as not disturbing the transportation of the electron or the positive hole.

### (3) Substrate for an Organic EL Element

Next, the substrate for an organic EL element of this embodiment will be explained. The substrate for an organic EL element of this embodiment is not particularly limited as long as it comprises the base material, electrode layer, photocatalyst processing layer and wettability changeable layer. For example, as needs arise, it may further comprise an insulation layer, a light shielding part, a barrier layer, or the like.

Here, in this embodiment, the wettability changeable layer may not have the wettability change. However, in this embodiment in particular, it is preferable that the wettability of the surface of the wettability changeable layer is changed in a pattern. Thereby, at the time of forming an organic EL element using the substrate for an organic EL element of this embodiment, the organic EL layer can be formed highly precisely along the wettability changeable pattern.

Since the method for forming such a wettability changeable pattern is same as that in the first embodiment, detailed explanation is omitted here.

### B. Organic EL Element

Next, the organic EL element of the present invention will be explained. The organic EL element of the present invention also has two embodiments according to the configuration difference. Hereinafter, each embodiment will be explained in detail.

### 1. First Embodiment

First, a first embodiment of the organic EL element of the present invention will be explained. The organic EL element of the first embodiment provides an organic electroluminescent element comprising an organic electroluminescent layer formed on the photocatalyst containing layer of the substrate for an organic electroluminescent element of the first embodiment, and

a counter electrode layer formed on the organic electroluminescent layer.

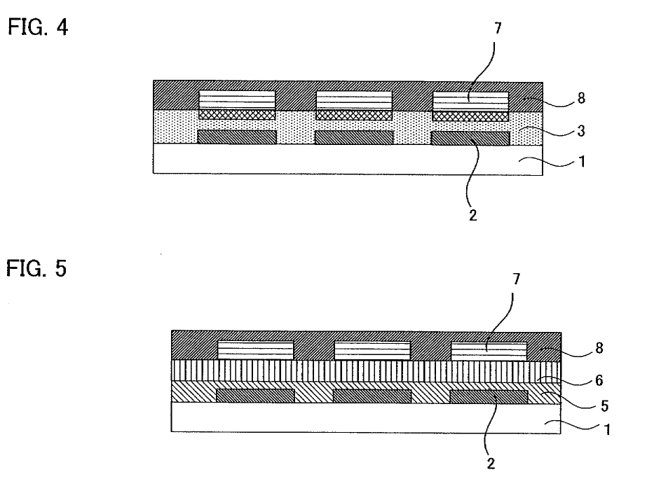

For example, as shown in FIG. 4, the organic EL element of this embodiment comprises a base material 1, an electrode layer 2 formed in a pattern on the base material 1, a photocatalyst containing layer 3 formed on the electrode layer 2, an organic EL layer 7 formed on the photocatalyst containing layer 3, and a counter electrode layer 8 formed on the organic EL layer.

According to this embodiment, since the photocatalyst containing layer to have the wettability change by the action of the photocatalyst accompanied by the energy irradiation is formed, the organic EL layer can be formed along the wettability changeable pattern formed on the photocatalyst containing layer. Therefore, the organic EL layer can be formed efficiently by a simple process. Moreover, since the activity of the photocatalyst is high in the photocatalyst containing layer, the wettability of the photocatalyst containing layer can be changed efficiently in a short period of time. Therefore, the pattern cannot be thickened by the energy spreading around, or the like so that the organic EL layer can be formed in a highly precise pattern.

Furthermore, since the activity of the photocatalyst is high in the photocatalyst containing layer, the film thickness of the photocatalyst containing layer can be made smaller. Therefore, the photocatalyst containing layer hardly lowering the charge injection efficiency can be obtained, and thus an organic EL element having high light emission characteristics can be provided.

Hereinafter, each configuration of the organic EL element of this embodiment will be explained. Since the base material, electrode layer and photocatalyst containing layer are same as those explained for the first embodiment of the above-mentioned “A. Substrate for an organic EL element”, detailed explanation is omitted here.

### (1) Organic EL Layer

The organic EL layer used in the present embodiment comprises one layer or a plurality of organic layers including at least a light emitting layer. That is, the organic EL layer is a layer including at least a light emitting layer, with the layer configuration of one organic layer or more. In general, in the case the organic EL layer is formed with the wet process by coating, since the lamination of a large number of layers is difficult according to the relationship with the solvent, it is formed as one layer or two layers of organic layers in many cases. However, it is also possible to provide a larger number of layers by skillfully using the organic material or employing the vacuum deposition method in a combination.

As the organic layer (s) formed in the organic EL layer in addition to the light emitting layer, a charge injecting layer such as a positive hole injecting layer and/or an electron injecting layer can be presented. Furthermore, as the other organic layers, a charge transporting layer such as a positive hole transporting layer for transporting the positive hole to the light emitting layer, and an electron transporting layer for transporting the electron to the light emitting layer can be presented. In general, these layers can be provided integrally with the charge injecting layer by providing the charge transporting function to the charge injecting layer. Additionally, as the organic layer formed in the organic EL layer, a layer for prevent ing piercing of the positive hole or the electron for improving the rebinding efficiency such as a carrier block layer can be presented.

In the present embodiment, for the photocatalyst containing layer of the substrate for an organic EL element, in the case the layer has the function to transport an electron or a positive hole, the photocatalyst containing layer may also play the role of a positive hole injecting layer, a positive hole transporting layer, or a positive hole injecting and transporting layer as a single layer having the both functions of the positive hole injecting function and the positive hole transporting function. In this case, as the organic EL layer, the positive hole injecting layer, the positive hole transporting layer, or the single positive hole injecting and transporting layer having the positive hole injecting function and the positive hole transporting function need not be provided.

Hereinafter, each configuration of such an organic EL layer will be explained.

a. Light Emitting Layer

As the light emitting layer as the essential configuration of the organic EL layer in the present embodiment, a light emitting material such as a pigment based light emitting material, a metal complex based light emitting material, and a polymer based light emitting material can be used.

As the pigment based light emitting material, for example, a cyclopentadiene derivative, a tetraphenyl butadiene derivative, a triphenyl amine derivative, an oxadiazol derivative, a pyrazoloquinoline derivative, a distyryl benzene derivative, a distyryl arylene derivative, a silol derivative, a thiophene ring compound, a pyridine ring compound, a perynon derivative, a perylene derivative, an oligothiophene derivative, a triphmanyl amine derivative, an oxadiazol dimer, a pyrazoline dimer or the like can be presented.

Moreover, as the metal complex based light emitting material, for example, metal complexes having an Al, a Zn, a Be or the like as the central metal, or a rare earth metal such as a Tb, an Eu, a Dy or the like, and an oxadiazol, a thiadiazol, a phenyl pyridine, a phenyl benzoimidazol, a quinoline structure or the like as the ligand, such as an aluminum quinolinol complex, a benzoquinolinol beryllium complex, a benzoxazol zinc complex, a benzothiazol zinc complex, an azomethyl zinc complex, a porphiline zinc complex, an europium complex or the like can be presented.

Furthermore, as the polymer based light emitting material, for example, a polyparaphenylene vinylene derivative, a polythiophene derivative, a polyparaphenylene derivative, a polysilane derivative, a polyacetylene derivative, a polyvinyl carbazol or the like, a polyfluolene derivative, a polyquinoxaline derivative, a polymer thereof or the like can be presented.

For the purpose of improving the light emitting efficiency, changing the light emitting wavelength or the like, an additive such as a doping agent may be added into the light emitting layer. As such a doping agent, for example, a perylene derivative, a coumarin derivative, a rubrene derivative, a quinacridone derivative, a squalium derivative, a porphiline derivative, a styryl based pigment, a tetracene derivative, a pyrazoline derivative, a decacyclene, a phenoxazone, a quinoxaline derivative, a carbazol derivative, and a fluolene derivative can be presented.

The thickness of the light emitting layer is not particularly limited as long as it is a thickness capable of providing the field for rebinding of the electron and the positive pole so as to provide the light emitting function. For example, it can be about 1 nm to 500 nm.

In the present embodiment, as mentioned above, in the case the photocatalyst containing layer also plays the role of the positive hole injecting layer, the positive hole transporting layer, or the positive hole injecting and transporting layer comprising a single layer having the positive hole injecting function and the positive hole transporting function, it is preferable to form a light emitting layer in a pattern as the organic EL layer on the photocatalyst containing layer. Since the light emitting layer is formed in a pattern so as to provide the light emitting layers of the three colors of red, green and blue, an organic EL element capable of providing the color display can be obtained.

As to the method for forming such a light emitting layer, it can be formed by coating a light emitting layer forming coating solution containing the materials on a photocatalyst containing layer with the wettability changeable pattern formed, or the like. The method for coating such a light emitting layer forming coating solution is not particularly limited as long as it is a method capable of coating on the wettability changeable pattern of the above-mentioned photocatalyst containing layer. However, it is preferably a method capable of forming the light emitting layer evenly and highly precisely. As such a coating method, for example, a dip coating method, a roll coating method, a blade coating method, a spin coating method, a micro gravure coating method, a gravure coating method, bar coating method, a wire bar coating method, a casting method, an inkjet method, a LB method, a flexo printing method, an offset printing method, a screen printing method or the like can be presented.

b. Charge Injecting and Transporting Layer

In the present embodiment, the charge injecting and transporting layer may be formed between the electrode layer or the counter electrode layer and the light emitting layer. The charge injecting and transporting layer here has the function of stably transporting the charge from the electrode layer or the counter electrode layer to the light emitting layer. By providing such a charge injecting and transporting layer between the light emitting layer and the electrode layer or the counter electrode layer, the charge injection to the light emitting layer can be stabilized so as to improve the light emitting efficiency.

As such a charge injecting and transporting layer, there are a positive hole injecting and transporting layer for transporting the positive hole injected from the anode into the light emitting layer, and an electron injecting and transporting layer for transporting the electron injected from the cathode into the light emitting layer. Hereinafter, the positive hole injecting and transporting layer and the electron injecting and transporting layer will be explained.

### (i) Positive Hole Injecting and Transporting Layer

The positive hole injecting and transporting layer used in the present embodiment may be one of the positive hole injecting layer for injecting the positive hole into the light emitting layer or the positive hole transporting layer for transporting the positive hole, a lamination of the positive hole injecting layer and the positive hole transporting layer, or a single layer having the both functions of the positive hole injecting function and the positive hole transporting function.

In the present embodiment, since the electrode layer of the substrate for an organic EL element is in general an anode, the positive hole injecting and transporting layer is formed between the light emitting layer and the electrode layer.

The material used for the positive hole injecting and transporting layer is not particularly limited as long as it is a material capable of stably transporting the positive hole injected from the anode into the light emitting layer. In addition to the compounds presented for the light emitting material of the light emitting layer, phenyl amine based, star burst type amine based, or phthalocyanine based, oxides such as a vanadium oxide, a molybdenum oxide, a ruthenium oxide, an aluminum oxide, and a titanium oxide, an amorphous carbon, a polyaniline, a polythiophene, a polyphenylene vinylene derivative or the like can be used. Specifically, a bis(N-(1-naphthyl-N-phenyl)benzidine (α-NPD), a 4,4,4-tris(3-methyl phenyl phenyl amino) triphenyl amine (MTDATA), a poly 3,4 ethylene dioxythiophene-polystyrene sulfonic acid (PEDOT-PSS), a polyvinyl carbazol (PVCz) or the like can be presented.

Moreover, the thickness of the positive hole injecting and transporting layer is not particularly limited as long as it is a thickness capable of sufficiently performing the function of injecting the positive hole from the anode and transporting the positive hole to the light emitting layer. Specifically, it is in a range of 0.5 nm to 1,000 nm, and preferably in a range of 10 nm to 500 nm.

### (ii) Electron Injecting and Transporting Layer

The electron injecting and transporting layer used in the present embodiment may be one of the electron injecting layer for injecting the electron into the light emitting layer or the electron transporting layer for transporting the electron, a lamination of the electron injecting layer and the electron transporting layer, or a single layer having the both functions of the electron injecting function and the electron transporting function.

In the present embodiment, since the counter electrode layer is in general a cathode, the electron injecting and transporting layer is formed between the light emitting layer and the counter electrode layer.

The material used for the electron injecting layer is not particularly limited as long as it is a material capable of stabilizing the electron injecting into the light emitting layer. In addition to the compounds presented for the light emitting material of the light emitting layer, alkaline metals such as an aluminum lithium alloy, a lithium fluoride, a strontium, a magnesium oxide, a magnesium fluoride, a strontium fluoride, a calcium fluoride, a barium fluoride, an aluminum oxide, a strontium oxide, a calcium, a polymethyl methacrylate, a sodium polystyrene sulfonate, a lithium, a cesium, and a cesium fluoride, halides of the alkaline metals, organic complexes of the alkaline metals or the like can be used.

The thickness of the electron injecting layer is not particularly limited as long as it is a thickness capable of sufficiently performing the electron injecting function.

Moreover, the material used for the electron transporting layer is not particularly limited as long as it is a material capable of transporting the electron injected from the electrode layer or the counter electrode layer into the light emitting layer. For example, a bathcuproine, a bathphenanthroline, a phenanthroline derivative, a triazol derivative, an oxadiazol derivative, a tris(8-quinolinolato)aluminum complex (Alq₃) or the like can be presented.

The thickness of the electron transporting layer is not particularly limited as long as it is a thickness capable of sufficiently performing the electron transporting function.

Furthermore, as the electron injecting and transporting layer comprising a single layer having the both functions of the electron injecting function and the electron transporting function, a metal doping layer with an alkaline metal or an alkaline earth metal doped to an electron transporting organic material may be formed so as to provide the electron injecting and transporting layer. As the electron transporting organic material, for example, a bathcuproine, a bathphenanthroline, a phenanthroline derivative or the like can be presented. As the doping metal, a Li, a Cs, a Ba, a Sr or the like can be presented.

The thickness of the electron injecting and transporting layer comprising a single layer is not particularly limited as long as it is a thickness capable of sufficiently performing the electron injecting function and the electron transporting function.

### (2) Counter Electrode Layer

The counter electrode layer used in the present embodiment is formed on the organic EL layer, and is an electrode facing the electrode layer of the substrate for an organic EL element. The counter electrode layer used in the present invention may either be an anode or a cathode. In general, it is formed as a cathode.

Moreover, the counter electrode layer may either be transparent or not, and it may be selected optionally according to the light taking out surface, the light receiving surface or the like. For example, in the case of taking out a light beam from the counter electrode layer side, the counter electrode layer needs to be transparent or semitransparent.

For the cathode, it is preferable to use a conductive material having a small work function for facilitating the electron injecting. For example, magnesium alloys such as MgAg, aluminum alloys such as AlLi, AlCa, and AlMg, alkaline metals and alkaline earth metals such as Li and Ca, alloys of the alkaline metals and the alkaline earth metals or the like can be presented.

Moreover, it is preferable that the counter electrode layer has a small resistance. In general, a metal material is used, but an organic compound or an inorganic compound may be used as well.

As for the other points of the counter electrode layer, they are the same as the ones described in the section for the Electrode layer in the column of “A. Substrate for an organic EL element” mentioned above. Thus, an explanation is omitted here.

### (3) Organic EL Element

The organic EL element of this embodiment is not particularly limited as long as it comprises the base material, electrode layer, photocatalyst containing layer, organic EL layer and counter electrode layer. For example, as need arise, it may suitably comprise an insulation layer, a barrier layer, or the like.

### 2. Second Embodiment

The second embodiment of the organic EL element of the present invention provides an organic electroluminescent element comprising

an organic electroluminescent layer formed on the wettability changeable layer of the substrate for an organic electroluminescent element of the second embodiment mentioned above, and a counter electrode layer formed on the organic electroluminescent layer.

For example as shown in FIG. 5, the organic EL element of this embodiment comprises a base material 1, an electrode layer 2 formed in a pattern on the base material 1, a photocatalyst processing layer 5 formed on the electrode layer 2, a wettability changeable layer 6 formed on the photocatalyst processing layer 5, an organic EL layer 7 formed on the wettability changeable layer 6, and a counter electrode layer 8 formed on the organic EL layer 7.

According to this embodiment, since the wettability changable layer to have the wettability change by the action of the photocatalyst accompanied by the energy irradiation is formed, the organic EL layer can be formed along the wettability changeable pattern formed on the wettability changable layer. Therefore, the organic EL layer can be formed efficiently by a simple process. Moreover, since the activity of the photocatalyst is high in the photocatalyst processing layer, the wettability of the wettability changable layer can be changed efficiently in a short period of time. Therefore, the pattern cannot be thickened by the energy spreading around, or the like so that the organic EL layer can be formed in a highly precise pattern.

Furthermore, since the activity of the photocatalyst is high in the photocatalyst processing layer, the film thickness of the photocatalyst processing layer and the wettability changable layer can be made smaller. Therefore, the photocatalyst processing layer and the wettability changable layer hardly lowering the charge injection efficiency can be obtained, and thus an organic EL element having high light emission characteristics can be provided.

The base material, electrode layer, photocatalyst processing layer and the organic EL layer used in the organic EL element of the present embodiment are same as those explained for the second embodiment of the above-mentioned “A. Substrate for an organic EL element”. For the organic EL layer and the counter electrode layer are same as those explained for the first embodiment. Accordingly, detailed explanation is omitted here.

In the present embodiment also, other than the base material, electrode layer, photocatalyst processing layer, wettability changeable layer, organic EL layer and counter electrode layer, the embodiment may comprises an insulation layer, a barrier layer, or the like as needs arise. In the case the photocatalyst processing layer and the wettability changeable layer has a function to transport the electron or the positive hole, the layers may also play the role of a positive hole injecting layer, a positive hole transporting layer, or a positive hole injecting and transporting layer as a single layer having the both functions of the positive hole injecting function and the positive hole transporting function.

The present invention is not limited to the embodiments. The embodiments are merely examples, and any one having the substantially same configuration as the technological idea disclosed in the claims of the present invention and the same effects is included in the technological scope of the present invention.

### EXAMPLES

Hereinafter, with reference to the examples, the present invention will be explained more specifically.

### Example

### Intensity Change Measurement of the Electron Spin Resonance Spectrum of the Photocatalyst Containing Layer

A photocatalyst containing layer forming coating solution was prepared by mixing 3 g of an isopropyl alcohol, 0.1 g of a tetraethoxy silane and 0.5 g of a titanium oxide sol solution (product name: STK-01, manufactured by ISHIHARA SANGYO KAISHA, LTD.) and agitating at 100° C. for 30 minutes. A 0.1 μm thickness photocatalyst containing layer for measurement was formed by coating the prepared photocatalyst containing layer forming coating solution on a washed non alkaline glass substrate of a 0.7 mm thickness by the spin coating method and heating at 150° C. for 60 minutes.

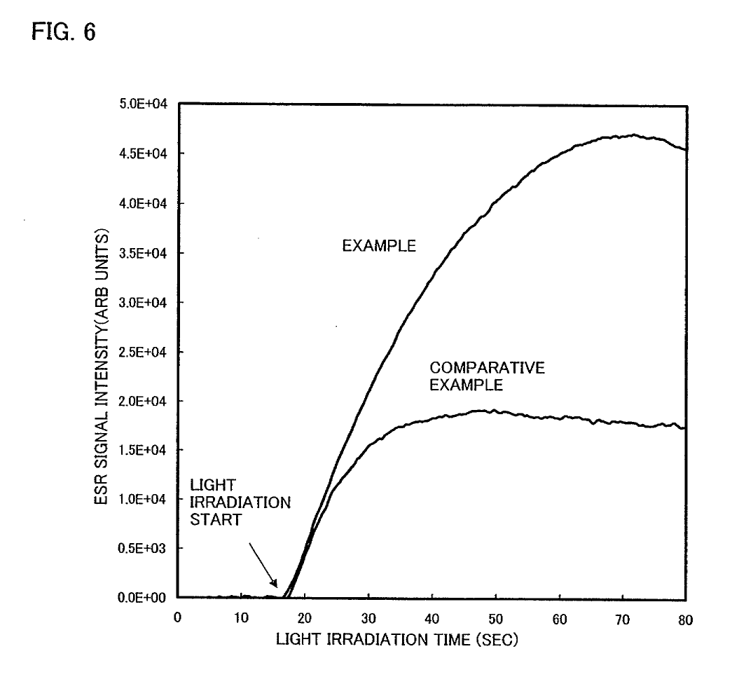

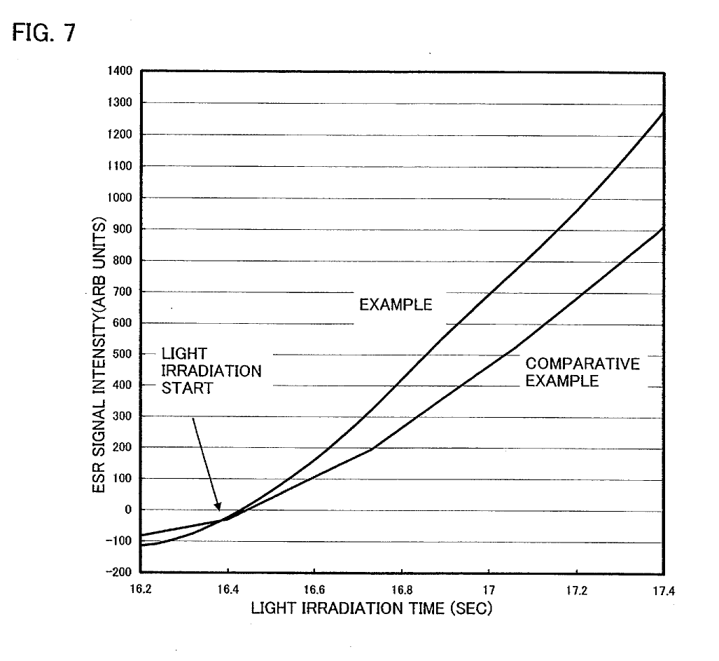

The electron spin resonance spectrum measurement was carried out while irradiating an ultraviolet ray of a high pressure mercury lamp for the photocatalyst containing layer for measurement by spin trapping. A graph showing the relationship between the light irradiation time and the signal intensity of the electron spin resonance derived from the hydroxy radical is shown in FIG. 6. Moreover, a graph showing the relationship between the light irradiation time immediately after the start of the light irradiation and the signal intensity of the electron spin resonance derived from the hydroxy radical is shown in FIG. 7. Thereby, it was confirmed that the electron resonance spectrum signal intensity derived from the hydroxy radical was raised to 1,200 times between 1 second to 2 seconds after the start of the exposure of the hydroxy radical.

### (Formation of the Substrate for an Organic El Element)

In the same manner as in the photocatalyst containing layer for measurement except that 0.005 g of a fluoroalkyl silane was added for providing the wettability changing characteristics to the photocatalyst containing layer forming coating solution, a transparent photocatalyst containing layer (positive hole transporting layer) having the wettability changing characteristics of a 80 nm thickness was formed on a washed ITO glass substrate. A substrate for an organic EL element, having a lyophilic region (energy irradiated portion) and a liquid repellent region (energy non irradiated portion) was formed by the light irradiation with a high pressure mercury lamp at a 70 mW/cm² illuminance for 50 seconds to the photocatalyst containing layer via a mask.

### (Formation of the Organic EL Element)

Next, a red light emitting layer pattern was formed by ejecting an ink for an EL light emitting layer preliminarily filtrated (ADS100TS) produced by American Dye Source, Inc. by the ink jet method to the lyophilic region of the photocatalyst containing layer (positive hole transporting layer) and drying at 100° C. for 1 hour. At the time, it was confirmed that the pattern width of the light emitting layer was formed as designed (same shape as the exposure pattern).

Subsequently, an organic EL element was produced by depositing Ca on the light emitting layer by a 500 Å thickness and furthermore, by depositing Ag as the counter electrode layer by a 2,500 Å thickness. With the ITO electrode side connected to an anode and the Ag electrode side to a cathode, a direct current was applied with a source meter. As a result, preferable red light emission was observed at the time of applying 10 V.

### Comparative Example

### Intensity Change Measurement of the Electron Spin Resonance Spectrum of the Photocatalyst Containing Layer

A 0.1 μm thickness photocatalyst containing layer for measurement was obtained in the same manner as in the photocatalyst containing layer for the intensity change measurement of the electron spin resonance spectrum of the example except that the time period for agitating the dispersion was changed to 5 minutes. The electron spin resonance spectrum measurement was carried out while irradiating an ultraviolet ray of a high pressure mercury lamp for the photocatalyst containing layer for measurement by spin trapping. A graph showing the relationship between the light irradiation time and the signal intensity of the electron spin resonance derived from the hydroxy radical is shown in FIG. 6. Moreover, a graph showing the relationship between the light irradiation time immediately after the start of the light irradiation and the signal intensity of the electron spin resonance derived from the hydroxy radical is shown in FIG. 7. Thereby, it was confirmed that the electron resonance spectrum signal intensity derived from the hydroxy radical was raised to 850 times between 1 second to 2 seconds after the start of the exposure.

### (Formation of the Substrate for an Organic EL Element)

In the same manner as in the photocatalyst containing layer for measurement except that 0.005 g of a fluoroalkyl silane was added for providing the wettability changing characteristics to the photocatalyst containing layer forming coating solution, a transparent photocatalyst containing layer (positive hole transporting layer) having the wettability changing characteristics of a 80 nm thickness was formed on a washed ITO glass substrate. A substrate for an organic EL element, having a lyophilic region (energy irradiated portion) and a liquid repellent region (energy non irradiated portion) was formed by the light irradiation consucted in the same manner as in the example to the photocatalyst containing layer.

### (Formation of the Organic EL Element)

Next, a red light emitting layer pattern was formed in the lyophilic region of the photocatalyst containing layer (positive hole transporting layer) in the same manner as in the example. Subsequently, an organic EL element was produced by depositing Ca on the light emitting layer by a 500 Å thickness and furthermore, depositing Ag as the counter electrode layer by a 2,500 Å thickness. With the ITO electrode side connected to an anode and the Ag electrode side to a cathode, a direct current was applied with a source meter. As a result, although red light emission was observed at the time of applying 10 V, the light emission pattern width was thicker than the design (exposure pattern) so that the desired light emission line and space were not obtained.

We claim:

1. A measurement method of a photocatalyst activity contained in a photocatalyst containing layer, which contains a photocatalyst and a binder, comprising the steps of:
setting the photocatalyst containing layer and a radical trapping agent in an electron spin resonance measuring device; and
measuring an electron spin resonance spectrum derived from a hydroxy radical while irradiating an ultraviolet ray to the photocatalyst containing layer set in the electron spin resonance measuring device.

2. The measurement method of a photocatalyst activity contained in a photocatalyst containing layer according to claim 1, wherein the photocatalyst containing layer is a layer showing a wettability change by an action of the photocatalyst accompanied by an energy irradiation.

3. The measurement method of a photocatalyst activity contained in a photocatalyst containing layer according to claim 1, wherein the binder is organopolysiloxane.

4. The measurement method of a photocatalyst activity contained in a photocatalyst containing layer according to claim 1, wherein the photocatalyst is at least one selected from the group consisting of titanium dioxide (TiO₂), zinc oxide (ZnO), tin oxide (SnO₂), strontium titanate (SrTiO₃), tungsten oxide (WO₃), bismuth oxide (Bi₂O₃), and iron oxide (Fe₂O₃).

5. The measurement method of a photocatalyst activity contained in a photocatalyst containing layer according to claim 1, wherein the photocatalyst is titanium dioxide (TiO₂).

6. A measurement method of a photocatalyst activity contained in a photocatalyst processing layer, which contains at least a photocatalyst, comprising steps of:
setting the photocatalyst processing layer and a radical trapping agent in an electron spin resonance measuring device; and
measuring an electron spin resonance spectrum derived from a hydroxy radical while irradiating an ultraviolet ray to the photocatalyst processing layer set in the electron spin resonance measuring device.

7. The measurement method of a photocatalyst activity contained in a photocatalyst processing layer according to claim 6, wherein a wettability changeable layer showing a wettability change by an action of the photocatalyst accompanied by an energy irradiation is formed on the photocatalyst processing layer.

8. The measurement method of a photocatalyst activity contained in a photocatalyst processing layer according to claim 7, wherein the wettability changeable layer contains organopolysiloxane.

9. The measurement method of a photocatalyst activity contained in a photocatalyst processing layer according to claim 6, wherein the photocatalyst is at least one selected from the group consisting of titanium dioxide (TiO₂), zinc oxide (ZnO), tin oxide (SnO₂), strontium titanate (SrTiO₃), tungsten oxide (WO₃), bismuth oxide (Bi₂O₃), and iron oxide (Fe₂O₃).

10. The measurement method of a photocatalyst activity contained in a photocatalyst processing layer according to claim 6, wherein the photocatalyst is titanium dioxide (TiO₂).
